(19) United States
(12) Patent Application Publication
(10) Pub. No.: US 2026/0251139 A1
(43) Pub. Date: Aug. 27, 2026

(54) PUMP DEVICE

(71) Applicant: PILLAR Corporation, Osaka (JP)

(72) Inventors: Takamasa Hamanaka, Osaka (JP); Keisuke Murata, Osaka (JP); Takashi Nishi, Osaka (JP)

(73) Assignee: PILLAR Corporation, Osaka (JP)

(21) Appl. No.: 19/546,597

(22) Filed: Feb. 23, 2026

(30) Foreign Application Priority Data
Feb. 27, 2025 (JP) 2025-029939

(51) Int. Cl. F04B 53/08; F04B 45/04; F04B 53/16

(52) U.S. Cl. CPC F04B 53/08; F04B 45/04; F04B 53/16

(57) ABSTRACT

Provided is a pump device capable of suppressing deterioration of a transport fluid due to thermal effects. A pump device of the present disclosure includes: a pump configured to suck and discharge a transport fluid; a casing having an accommodation space in which the pump is accommodated; and a heat-generating component placed in the accommodation space together with the pump, and the casing includes an intake port for introducing gas for cooling the heat-generating component, into the accommodation space therethrough, and an exhaust port, located above the intake port, for discharging the gas around the heat-generating component to the outside of the casing therethrough.

### TECHNICAL FIELD

The present disclosure relates to a pump device. This application claims priority on Japanese Patent Application No. 2025-029939 filed on February 27, 2025, the entire content of which is incorporated herein by reference.

### BACKGROUND ART

As a pump that feeds a chemical solution (resist solution or the like), for example, in a manufacturing process for semiconductors or the like, for example, a diaphragm pump described in PATENT LITERATURE 1 is known. In this diaphragm pump, when a motor is driven to reciprocate a piston within a cylinder, a rolling diaphragm becomes deformed to change the volume of a pump chamber, thereby sucking the chemical solution into the pump chamber and discharging the chemical solution to the outside.

### CITATION LIST

### PATENT LITERATURE

PATENT LITERATURE 1: Japanese Laid-Open Patent Publication No. 2024-075196

### SUMMARY OF THE INVENTION

### TECHNICAL PROBLEM

Generally, the above diaphragm pump is accommodated in a casing together with components associated with the pump, in order to improve portability and protect drive components. However, the components associated with the pump may include a heat-generating component such as a pressure sensor for detecting the pressure of a transport fluid. In this case, if the temperature inside the casing is increased by heat generated by the heat-generating component, the temperature of the chemical solution in the pump may increase, which may deteriorate the chemical solution.

The present disclosure has been made in view of such circumstances, and an object of the present disclosure is to provide a pump device capable of suppressing deterioration of a transport fluid due to thermal effects.

### SOLUTION TO PROBLEM

(1) A pump device of the present disclosure is a pump device including: a pump configured to suck and discharge a transport fluid; a casing having an accommodation space in which the pump is accommodated; and a heat-generating component placed in the accommodation space together with the pump, wherein the casing includes an intake port for introducing gas for cooling the heat-generating component, into the accommodation space therethrough, and an exhaust port, located above the intake port, for discharging the gas around the heat-generating component to the outside of the casing therethrough.

With the pump device of the present disclosure, the heat-generating component, which is placed in the accommodation space of the casing, is cooled by the gas introduced through the intake port of the casing. The gas warmed around the heat-generating component is discharged to the outside of the casing through the exhaust port. Accordingly, the temperature of the heat-generating component becomes less likely to increase, and thus an increase in the temperature of the transport fluid caused by an increase in the temperature of the heat-generating component can be suppressed. As a result, deterioration of the transport fluid due to thermal effects can be suppressed.

(2) The pump device of (1) above preferably further includes a heat dissipation portion placed in the accommodation space and configured to dissipate heat generated by the heat-generating component.

In this case, owing to the heat dissipation portion, the temperature of the heat-generating component becomes further less likely to increase, and thus an increase in the temperature of the transport fluid caused by an increase in the temperature of the heat-generating component can be further suppressed.

(3) The pump device of (1) or (2) above preferably further includes a flow rectifying portion configured to rectify flow of the gas introduced into the accommodation space through the intake port.

In this case, the flow of the gas introduced into the accommodation space of the casing through the intake port is rectified by the flow rectifying portion, and thus the heat-generating component can be efficiently cooled.

(4) In the pump device of (3) above, preferably, the casing includes a first side wall and a second side wall facing each other across the accommodation space, the intake port is provided at a lower side of the first side wall, the heat-generating component is a pressure sensor located at an upper side and the second side wall side of the accommodation space and configured to detect a pressure of the transport fluid, and the flow rectifying portion includes a first flow rectifying member configured to guide the gas introduced into the accommodation space through the intake port, from a lower side and the first side wall side of the accommodation space to the upper side and the second side wall side of the accommodation space.

In this case, the first flow rectifying member can efficiently cause the gas introduced into the accommodation space through the intake port to flow toward the pressure sensor. Accordingly, the pressure sensor can be efficiently cooled.

(5) In the pump device of (4) above, preferably, the casing includes a bottom wall placed below the accommodation space, the pump device further includes a support member provided to the bottom wall and configured to support the pump at a predetermined height from the bottom wall in the accommodation space, and the support member also serves as the first flow rectifying member.

In this case, since the support member, which supports the pump at a predetermined height from the bottom wall of the casing, also serves as the first flow rectifying member which guides the flow of the gas, the configuration of the pump device can be simplified.

(6) Preferably, the pump device of (4) or (5) above further includes a pipe which is placed between the pressure sensor and the second side wall in the accommodation space and through which the transport fluid flows, and the flow rectifying portion includes a second flow rectifying member separating the pressure sensor and the pipe from each other.

In this case, the second flow rectifying member can inhibit the gas warmed around the pressure sensor from flowing toward the pipe side. Accordingly, an increase in the temperature of the transport fluid flowing through the pipe can be suppressed.

(7) Preferably, the pump device of (6) above further includes a heat dissipation portion placed in the accommodation space and configured to dissipate heat generated by the heat-generating component, the heat dissipation portion includes a first heat dissipation member covering the pressure sensor, and a second heat dissipation member configured to dissipate heat generated by the pressure sensor, from an end portion on the pipe side of the first heat dissipation member to the casing, and the second heat dissipation member also serves as the second flow rectifying member.

In this case, since the second heat dissipation member, which dissipates heat generated by the pressure sensor from the first heat dissipation member to the casing, also serves as the second flow rectifying member separating the pressure sensor and the pipe, the configuration of the pump device can be further simplified.

(8) In the pump device of any of (4) to (7) above, preferably, the exhaust port is provided above the intake port in the first side wall, the flow rectifying portion includes a third flow rectifying member placed so as to extend in an up-down direction at the first side wall side of the accommodation space and above the intake port, and an exhaust flow path for guiding the gas to the exhaust port is formed between the third flow rectifying member and the first side wall.

In this case, the exhaust flow path, which is formed between the first side wall and the third flow rectifying member, can guide the gas to the exhaust port. Accordingly, the gas warmed around the pressure sensor can be efficiently discharged to the outside of the casing through the exhaust port.

(9) Preferably, the pump device of (8) above further includes: a motor placed above the pump in the accommodation space; and a coupling member placed in the accommodation space, extending in the up-down direction, and coupling end portions on the first side wall side of the pump and the motor with each other, and the coupling member also serves as the third flow rectifying member.

In this case, since the coupling member, which couples the end portions on the first side wall side of the pump and the motor with each other, also serves as the third flow rectifying member which forms the exhaust flow path for guiding the gas to the exhaust port, the configuration of the pump device can be further simplified.

(10) In the pump device of (8) or (9) above, preferably, the flow rectifying portion includes a fourth flow rectifying member placed between a lower end portion of the third flow rectifying member and the first side wall and closing a lower end of the exhaust flow path.

In this case, the fourth flow rectifying member can prevent the gas flowing from the upper side toward the lower side of the exhaust flow path from merging with the gas introduced through the intake port. Accordingly, the gas warmed around the pressure sensor can be inhibited from circulating in the accommodation space.

(11) In the pump device of any of (3) to (10) above, preferably, the exhaust port is composed of a plurality of slits formed in the casing and extending in one direction, and the flow rectifying portion includes a plurality of fin members provided so as to protrude from edge portions, extending in the one direction, of the slits toward the accommodation space and extending along the one direction.

In this case, the gas is rectified by the plurality of fin members extending along the one direction at the edge portions of the plurality of slits which are the exhaust port of the casing, and thus the gas can be inhibited from staying in the accommodation space.

### ADVANTAGEOUS EFFECTS OF THE INVENTION

According to the present disclosure, it is possible to suppress deterioration of the transport fluid due to thermal effects.

### BRIEF DESCRIPTION OF DRAWINGS

FIG. 1 is a perspective view showing a pump device according to a first embodiment of the present disclosure.

FIG. 2 is a cross-sectional view showing a pump of the pump device and components around the pump.

FIG. 3 is a cross-sectional view showing the pump in a state where a piston of the pump device has moved to a rearmost position.

FIG. 4 is a side view of the pump device as seen from a left side.

FIG. 5 is a side view of the pump device as seen from a rear side.

FIG. 6 is a plan view of the pump device as seen from above.

FIG. 7 is a perspective view of a top wall of a casing in a pump device according to a second embodiment of the present disclosure as seen from an accommodation space side.

FIG. 8 is a perspective view of a first side wall of the casing as seen from the accommodation space side.

### DETAILED DESCRIPTION

Next, preferred embodiments will be described with reference to the accompanying drawings.

### First Embodiment

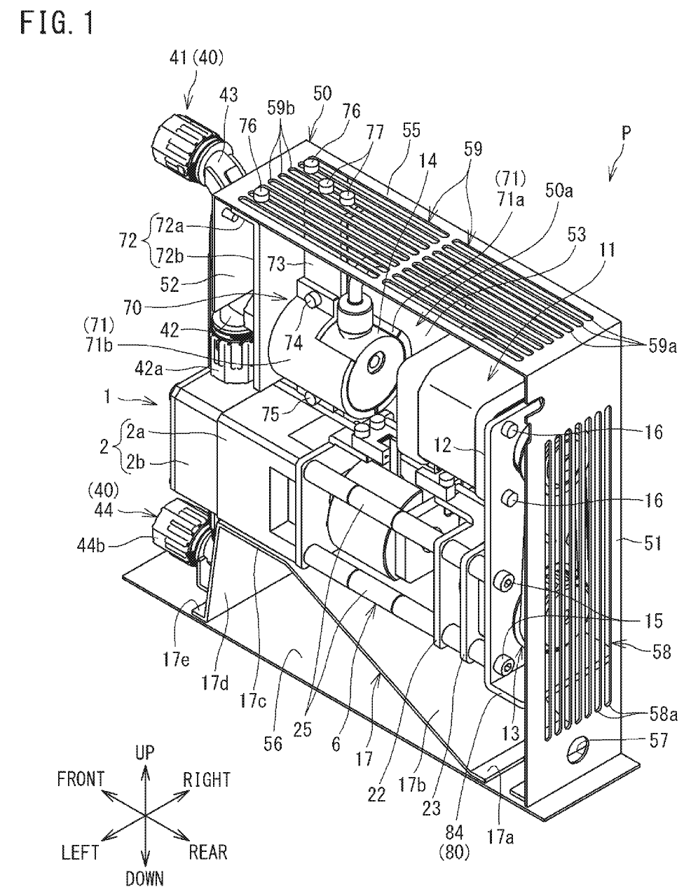

FIG. 1 is a perspective view showing a pump device P according to a first embodiment of the present disclosure. The pump device P includes a pump 1, a motor 11, a coupling member 12, a transmission mechanism 13, a pressure sensor 14, a pair of pipes 40, and a casing 50. Hereinafter, in this specification, directions “up”, “down”, “right”, “left”, “front”, and “rear” refer to directions shown in FIG. 1.

The pump 1 sucks and discharges a transport fluid. The motor 11, the coupling member 12, the transmission mechanism 13, the pressure sensor 14, and the pipe 40 are components associated with the pump 1. The pump 1, the motor 11, the coupling member 12, the transmission mechanism 13, the pressure sensor 14, and a part of each pipe 40 are accommodated in the casing 50.

### Pump

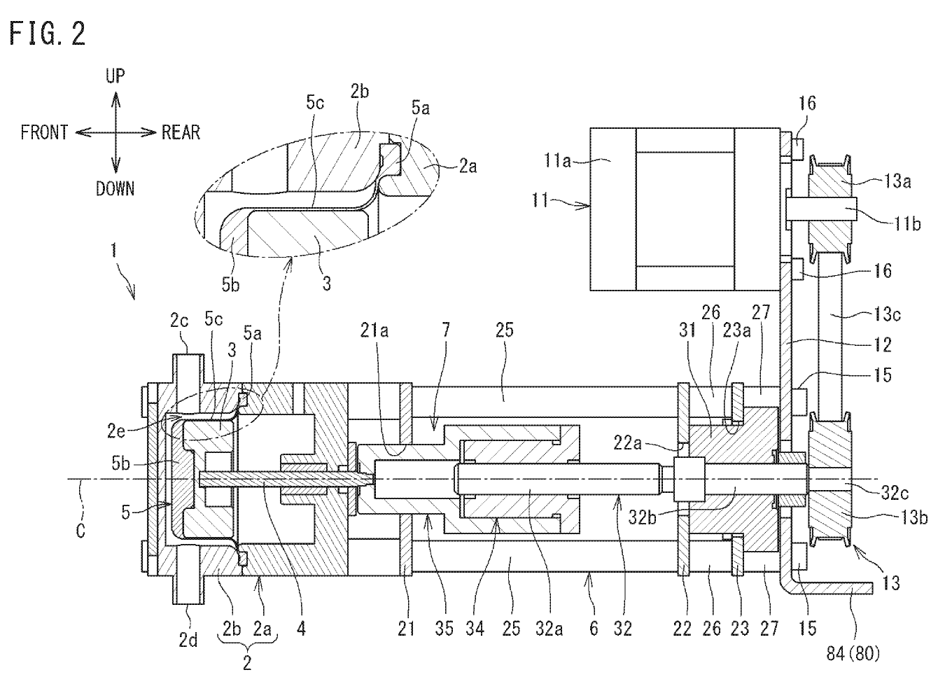

FIG. 2 is a cross-sectional view showing the pump 1 and components around the pump 1. In FIG. 1 and FIG. 2, the pump 1 is, for example, a diaphragm pump (dispense pump) that feeds a transport fluid such as a chemical solution used in a semiconductor manufacturing apparatus, in a fixed amount at a time. The pump 1 includes a housing 2, a piston 3, a shaft 4, a rolling diaphragm 5, a mounting frame 6, and a linear motion mechanism 7.

The housing 2 includes a cylinder 2a and a pump head 2b. The cylinder 2a is formed in a quadrangular tube shape with a bottom and is open rearward. The pump head 2b is formed in a quadrangular tube shape with a bottom and is open frontward. The pump head 2b is attached to the cylinder 2a so as to close the rear opening of the cylinder 2a. The internal space of the pump head 2b, together with the internal space of the cylinder 2a, constitutes a space for accommodating the piston 3 therein.

A first connection port 2c is formed at the upper side of the peripheral wall of the pump head 2b so as to extend therethrough. A first pipe 41 (described later) is connected to the first connection port 2c. A second connection port 2d is formed at the lower side of the peripheral wall of the pump head 2b so as to extend therethrough. A second pipe 44 (described later) is connected to the second connection port 2d. Of the first connection port 2c and the second connection port 2d, one functions as a suction port through which the transport fluid is sucked, and the other functions as a discharge port through which the transport fluid is discharged.

The piston 3 is placed within the housing 2 and is reciprocally movable in the front-rear direction relative to the housing 2. The piston 3 is formed in a circular column shape. The shaft 4 extends in the front-rear direction through the cylinder 2a. A front end portion of the shaft 4 is connected to the piston 3. A rear end portion of the shaft 4 is in contact with a front end portion of a coupling body 35 (described later) of the linear motion mechanism 7.

The rolling diaphragm 5 is placed within the housing 2. The rolling diaphragm 5 is made of a resin such as PTFE (polytetrafluoroethylene), for example. The rolling diaphragm 5 includes a fixed portion 5a attached to the housing 2, a movable portion 5b attached to the piston 3, and a connecting portion 5c connecting the fixed portion 5a and the movable portion 5b.

The fixed portion 5a is formed in an annular shape and is fixed by being sandwiched between the cylinder 2a and the pump head 2b. The movable portion 5b is formed in a disk shape and is fixed to a front end face of the piston 3. The movable portion 5b reciprocates integrally with the piston 3 in the front-rear direction. The connecting portion 5c is formed thin (in a thin film shape) and has flexibility. The connecting portion 5c connects a radially inner end of the fixed portion 5a and a radially outer end of the movable portion 5b.

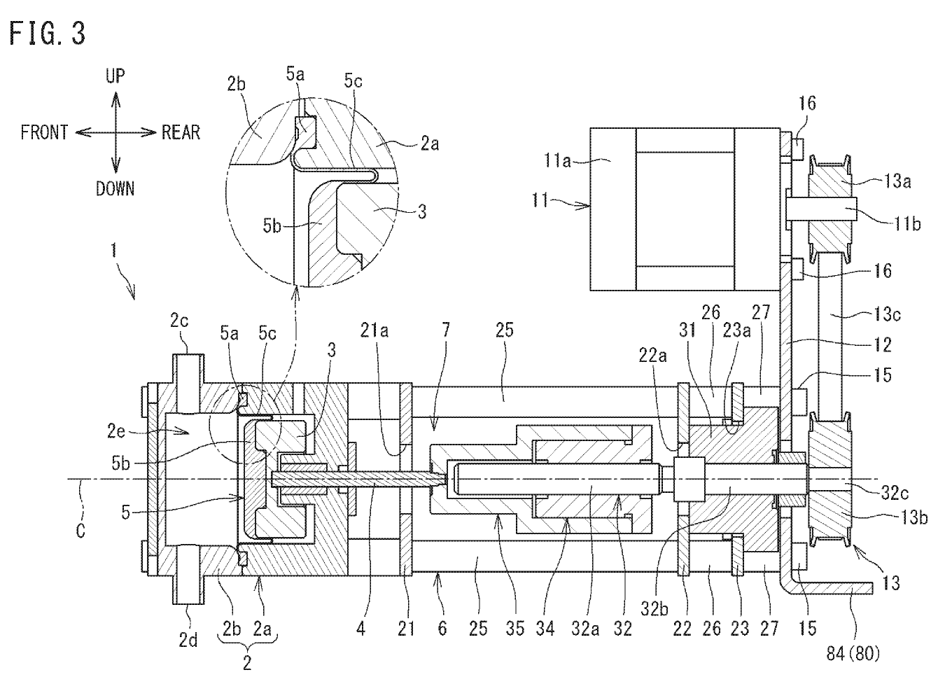

As shown in FIG. 2, when the piston 3 is at a frontmost position, the connecting portion 5c is deformed into a cylindrical shape along the outer peripheral surface of the piston 3, and the entire inner peripheral surface of the connecting portion 5c is in close contact with the outer peripheral surface of the piston 3. When the piston 3 moves to a rearmost position (see FIG. 3) from this state, the connecting portion 5c becomes deformed so as to bend into a U-shaped cross section between the inner peripheral surface of the cylinder 2a and the outer peripheral surface of the piston 3. In this state, the connecting portion 5c is in close contact with both the inner peripheral surface of the cylinder 2a and the outer peripheral surface of the piston 3.

FIG. 3 is a cross-sectional view showing the pump 1 in a state where the piston 3 has moved to the rearmost position. In FIG. 2 and FIG. 3, a pump chamber 2e partitioned by the rolling diaphragm 5 is formed within the housing 2. The pump chamber 2e is formed by being enclosed by the rolling diaphragm 5 and the pump head 2b. The pump chamber 2e communicates with both the first connection port 2c and the second connection port 2d of the pump head 2b. The volume of the pump chamber 2e changes in accordance with the reciprocating movement of the piston 3.

In FIG. 1 and FIG. 2, the mounting frame 6 is a frame to which the linear motion mechanism 7 is attached at the rear of the housing 2. The mounting frame 6 includes a first partition plate 21, a second partition plate 22, a third partition plate 23, a plurality of first spacers 25, a plurality of second spacers 26, and a plurality of third spacers 27. The first partition plate 21, the second partition plate 22, and the third partition plate 23 are all formed in the same square shape. The first spacers 25, the second spacers 26, and the third spacers 27 are all formed in a cylindrical shape and extend in the front-rear direction.

At the rear of the cylinder 2a, the first partition plate 21, the plurality of first spacers 25, the second partition plate 22, the plurality of second spacers 26, the third partition plate 23, and the plurality of third spacers 27 are placed in this order from the front side. The plurality of first spacers 25 are placed between the four corners of the first partition plate 21 and the four corners of the second partition plate 22. The plurality of second spacers 26 are placed between the four corners of the second partition plate 22 and the four corners of the third partition plate 23. The plurality of third spacers 27 are placed at the four corners of the third partition plate 23.

The mounting frame 6 is fixed to the housing 2 together with the coupling member 12 by a plurality of bolts 15. Each bolt 15 penetrates the coupling member 12, the inside of the third spacer 27, the third partition plate 23, the inside of the second spacer 26, the second partition plate 22, the inside of the first spacer 25, and the first partition plate 21 in this order and is screwed into a threaded hole (not shown) formed in the cylinder 2a.

The linear motion mechanism 7 is a mechanism that converts rotational motion of the motor 11 into linear motion to reciprocate the piston 3. In the present embodiment, the linear motion mechanism 7 is, for example, a ball screw mechanism and includes a support portion 31, a shaft body 32, a nut 34, the coupling body 35, and a plurality of balls (not shown).

The support portion 31 is formed in a tubular shape and is fixed to the mounting frame 6 at the rear of the housing 2. The support portion 31 of the present embodiment is fixed to the third partition plate 23 in a state of penetrating a through hole 23a formed in the third partition plate 23.

The shaft body 32 is placed coaxially with an axis C of the shaft 4. The shaft body 32 includes an external thread portion 32a, a shaft main body portion 32b supported by the support portion 31, and a connection portion 32c to which the transmission mechanism 13 is connected.

The shaft main body portion 32b is inserted into the inner periphery of the support portion 31 through a through hole 22a formed in the second partition plate 22. The shaft main body portion 32b is rotatably supported by the support portion 31. The external thread portion 32a extends frontward from the front end of the shaft main body portion 32b and is placed between the first partition plate 21 and the second partition plate 22.

A rear end portion of the shaft main body portion 32b protrudes rearward through the coupling member 12. The connection portion 32c extends rearward from the rear end of the shaft main body portion 32b. A driven pulley 13b (described later) of the transmission mechanism 13 is connected to the connection portion 32c. Accordingly, the shaft body 32 is rotationally driven by the motor 11 via the transmission mechanism 13.

In FIG. 2 and FIG. 3, the nut 34 is screwed onto the external thread portion 32a of the shaft body 32 via the plurality of balls. The nut 34 is prevented from rotating about the axis C together with the external thread portion 32a, by a restricting means (not shown) provided to the mounting frame 6. Accordingly, when the shaft body 32 rotates about the axis C relative to the support portion 31, the external thread portion 32a rotates, thereby allowing the nut 34 to reciprocate in the axial direction relative to the external thread portion 32a (see also FIG. 3).

The coupling body 35 couples the nut 34 with the shaft 4. The coupling body 35 is formed in a tubular shape with a bottom and is open rearward. The nut 34 is inserted and fixed to the inner periphery of a rear portion of the coupling body 35. A front portion of the coupling body 35 is inserted into a through hole 21a formed in the first partition plate 21. A front end portion of the coupling body 35 is fixed to the rear end portion of the shaft 4. Accordingly, the piston 3 reciprocates in the front-rear direction together with the nut 34 via the shaft 4 and the coupling body 35.

The motor 11 is a drive source that rotationally drives the shaft body 32 of the linear motion mechanism 7. The motor 11 is placed above a rear portion of the pump 1. The motor 11 includes a motor main body 11a and an output shaft 11b. The motor main body 11a is fixed to the coupling member 12 by a plurality of bolts 16 in a state of being in contact with an upper portion of the front surface of the coupling member 12. The output shaft 11b protrudes rearward from the motor main body 11a through the coupling member 12. At the rear of the coupling member 12, the output shaft 11b of the motor 11 is placed parallel to the connection portion 32c of the shaft body 32.

The coupling member 12 is, for example, a rectangular plate member and extends in the up-down direction at the rear of the pump 1. A lower portion of the coupling member 12 is fixed to the housing 2 of the pump 1 via the mounting frame 6 by the bolts 15 as described above. The motor main body 11a of the motor 11 is fixed to an upper portion of the coupling member 12 by the bolts 16 as described above. Accordingly, the coupling member 12 connects rear end portions of the pump 1 and the motor 11 to each other and holds the motor 11 in a state where the motor 11 is spaced upward from the pump 1.

The transmission mechanism 13 is a mechanism that transmits rotation of the output shaft 11b of the motor 11 to the connection portion 32c of the shaft body 32. The transmission mechanism 13 is placed at the rear of the coupling member 12. The transmission mechanism 13 includes a drive pulley 13a, the driven pulley 13b, and a belt 13c.

The drive pulley 13a is connected to the output shaft 11b of the motor 11 and is rotationally driven by the output shaft 11b. The driven pulley 13b is connected to the connection portion 32c of the shaft body 32 and is rotatable about the axis C together with the connection portion 32c. The outer diameter of the driven pulley 13b is larger than the outer diameter of the drive pulley 13a. The belt 13c is formed in an endless shape and is looped over the drive pulley 13a and the driven pulley 13b.

When the output shaft 11b of the motor 11 is rotated, the rotation of the output shaft 11b is transmitted to the connection portion 32c of the shaft body 32 via the drive pulley 13a, the belt 13c, and the driven pulley 13b. At this time, since the outer diameter of the driven pulley 13b is larger than the outer diameter of the drive pulley 13a, the rotation of the output shaft 11b is decelerated at a predetermined speed reduction ratio and transmitted to the connection portion 32c of the shaft body 32.

With the above configuration, when the motor 11 is driven, the shaft body 32 of the linear motion mechanism 7 rotates about the axis C via the transmission mechanism 13 from the output shaft 11b. When the shaft body 32 rotates, the rotational motion thereof is converted into linear motion in the axial direction by the nut 34, and the piston 3 reciprocates in the axial direction via the coupling body 35 and the shaft 4. As the piston 3 reciprocates, the rolling diaphragm 5 becomes deformed, and the volume of the pump chamber 2e changes.

At this time, when the piston 3 moves rearward, a suction process (see FIG. 3) in which the transport fluid is sucked into the pump chamber 2e through the first connection port 2c (or the second connection port 2d) is performed. When the piston 3 moves frontward, a discharge process (see FIG. 2) in which the transport fluid in the pump chamber 2e is discharged through the second connection port 2d (or the first connection port 2c) is performed. By alternately repeating the suction process and the discharge process in this manner, a constant amount of the transport fluid is fed from the pump 1.

### Pipe and Pressure Sensor

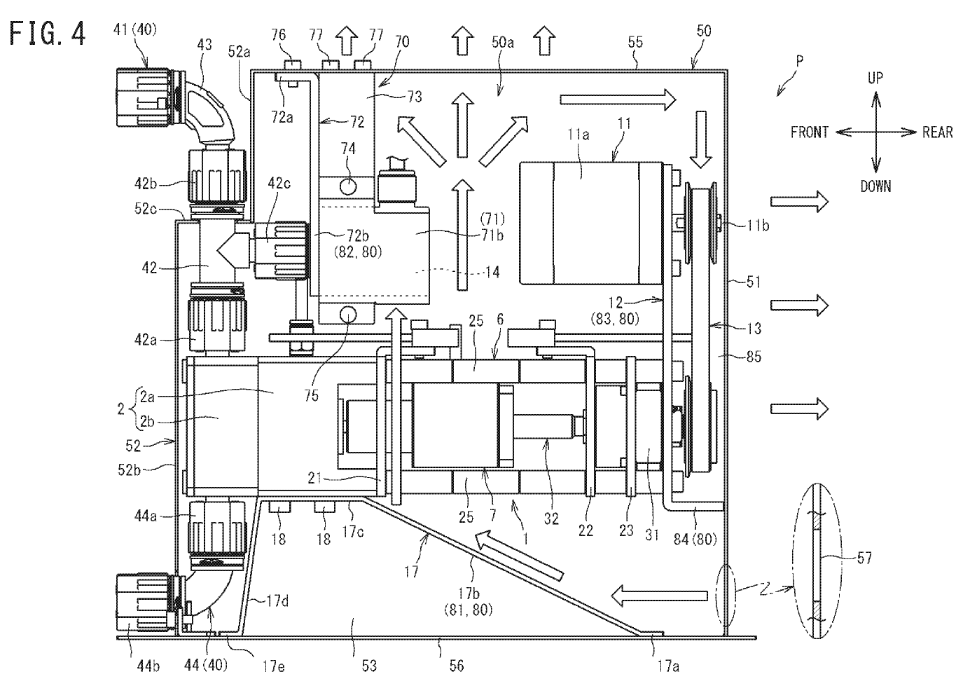

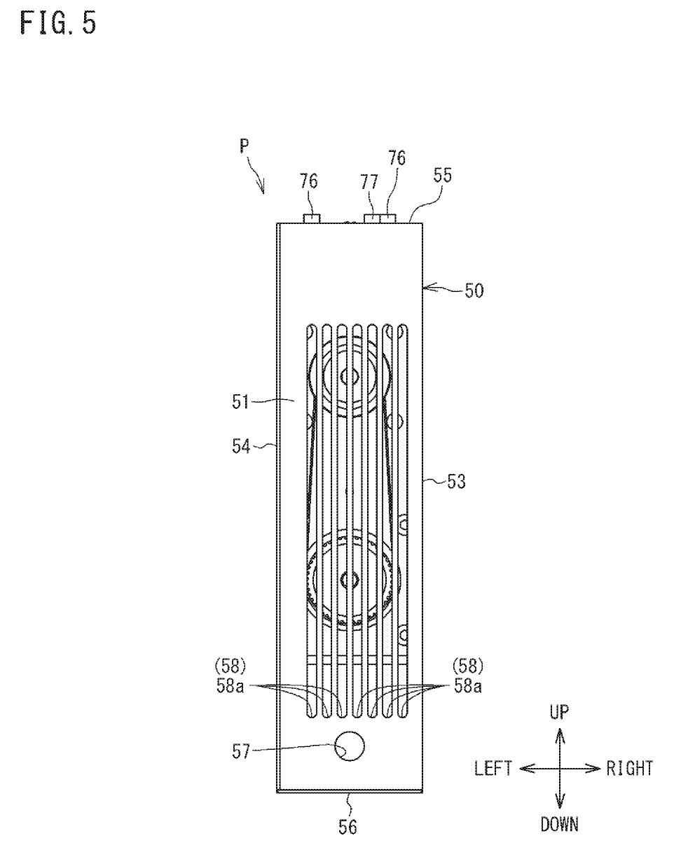

FIG. 4 is a side view of the pump device P as seen from the front side. In FIG. 1 and FIG. 4, a fourth side wall 54 (see FIG. 5) of the casing 50, which will be described later, is not shown. In FIG. 1 and FIG. 4, the pair of pipes 40 of the pump device P are composed of the first pipe 41 and the second pipe 44 connected to the pump 1. The transport fluid flows through each of the first pipe 41 and the second pipe 44. The first pipe 41 includes a lower pipe portion 42 and an upper pipe portion 43 connected to the lower pipe portion 42.

The lower pipe portion 42 is, for example, a T-shaped joint pipe and includes a first connection end portion 42a which is open downward, a second connection end portion 42b which is open upward, and a third connection end portion 42c which is open rearward. The first connection end portion 42a and the third connection end portion 42c of the lower pipe portion 42 are placed in an accommodation space 50a of the casing 50. The lower pipe portion 42 is placed between the pressure sensor 14 and a lower plate portion 52b of a second side wall 52, which will be described later, in the accommodation space 50a.

The first connection end portion 42a of the lower pipe portion 42 is connected to the first connection port 2c (see FIG. 2) of the housing 2 of the pump 1. The second connection end portion 42b of the lower pipe portion 42 is placed outside the casing 50 through a step plate portion 52c (described later) of the second side wall 52.

The upper pipe portion 43 of the first pipe 41 is, for example, an elbow-type joint pipe and is placed outside the casing 50. One end of the upper pipe portion 43 is connected to the second connection end portion 42b of the lower pipe portion 42. The other end of the upper pipe portion 43 is open frontward.

The second pipe 44 is, for example, an elbow-type joint pipe and includes a first connection end portion 44a which is open upward and a second connection end portion 44b which is open frontward. The first connection end portion 44a of the second pipe 44 is connected to the second connection port 2d (see FIG. 2) of the housing 2 of the pump 1. The second connection end portion 44b of the second pipe 44 is placed outside the casing 50 through the lower plate portion 52b (described later) of the second side wall 52.

The pressure sensor 14 is attached to the third connection end portion 42c of the lower pipe portion 42 of the first pipe 41. The outer shape of the pressure sensor 14 is formed, for example, as a circular column shape. The pressure sensor 14 detects the pressure of the transport fluid flowing through the lower pipe portion 42.

The pressure sensor 14 contains an electronic component (not shown) that generates heat when energized. Therefore, the pressure sensor 14 is a heat-generating component placed in the accommodation space 50a of the casing 50 together with the pump 1. Here, the term “heat-generating component” refers to a component that generates heat and that is placed in the accommodation space 50a of the casing 50 together with the pump 1 and is placed at a position where the transport fluid sucked and discharged by the pump 1 is affected by heat.

### Casing

The casing 50 is formed in a substantially rectangular parallelepiped shape. The accommodation space 50a, in which the pump 1, the motor 11, the coupling member 12, the transmission mechanism 13, the pressure sensor 14, and a part of each pipe 40 are accommodated, is formed inside the casing 50. The casing 50 includes a first side wall 51, the second side wall 52, a third side wall 53, the fourth side wall 54 (see FIG. 5), a top wall 55, and a bottom wall 56. The first side wall 51, the second side wall 52, the third side wall 53, the fourth side wall 54, the top wall 55, and the bottom wall 56 are each a plate member.

The first side wall 51 is a rear side wall of the casing 50. The second side wall 52 is a front side wall of the casing 50. The first side wall 51 and the second side wall 52 face each other across the accommodation space 50a. The second side wall 52 includes an upper plate portion 52a and the lower plate portion 52b extending in the up-down direction, and the step plate portion 52c extending in the front-rear direction. The upper plate portion 52a is placed rearward of the lower plate portion 52b and is shorter in the up-down direction than the lower plate portion 52b. The step plate portion 52c couples the lower end of the upper plate portion 52a with the upper end of the lower plate portion 52b.

The third side wall 53 is a right side wall of the casing 50. The rear edge of the third side wall 53 is connected to the right edge of the first side wall 51. The front edge of the third side wall 53 is connected to the right edge of the second side wall 52. The dimension in the up-down direction of the third side wall 53 is the same as that of the first side wall 51 (second side wall 52). The dimension in the front-rear direction of the third side wall 53 is longer than the dimension in the left-right direction of the first side wall 51 (second side wall 52).

FIG. 5 is a side view of the pump device P as seen from the rear side. In FIG. 4 and FIG. 5, the fourth side wall 54 is a left side wall of the casing 50. The fourth side wall 54 faces the third side wall 53 across the accommodation space 50a. The rear edge of the fourth side wall 54 is connected to the left edge of the first side wall 51. Although not shown, the front edge of the fourth side wall 54 is connected to the left edge of the second side wall 52. The dimensions in the up-down direction and the left-right direction of the fourth side wall 54 are the same as those of the third side wall 53.

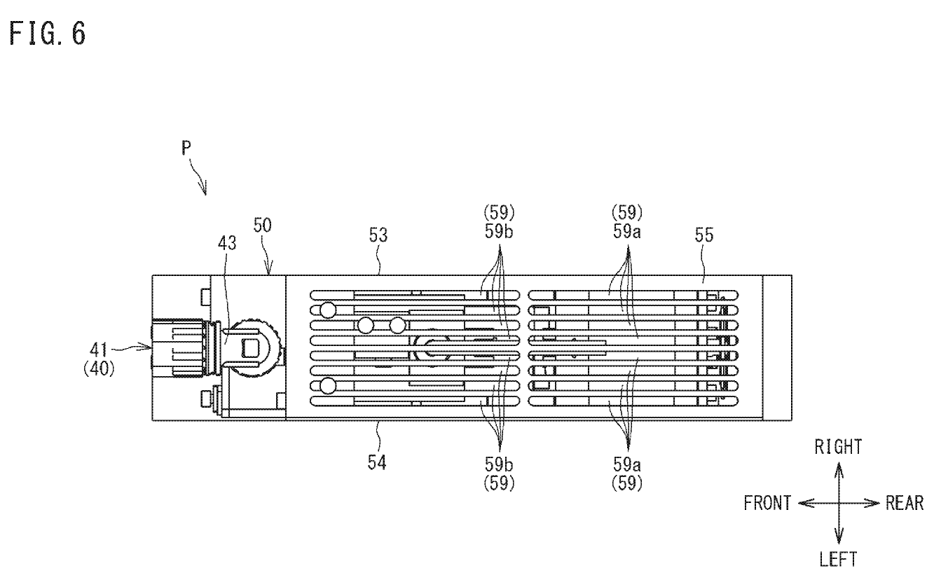

FIG. 6 is a plan view of the pump device P as seen from above. In FIG. 4 to FIG. 6, the top wall 55 is placed above the accommodation space 50a of the casing 50. The rear edge and the front edge of the top wall 55 are connected to the upper edge of the first side wall 51 and the upper edge of the second side wall 52 (upper plate portion 52a), respectively. The right edge and the left edge of the top wall 55 are connected to the upper edge of the third side wall 53 and the upper edge of the fourth side wall 54, respectively.

The bottom wall 56 is placed below the accommodation space 50a of the casing 50. The bottom wall 56 is longer in the front-rear direction than the top wall 55. The lower edge of the first side wall 51 is connected to a rear end portion of the upper surface of the bottom wall 56. The lower edge of the second side wall 52 (lower plate portion 52b) is connected to a front end portion of the upper surface of the bottom wall 56. The lower edge of the third side wall 53 and the lower edge of the fourth side wall 54 are connected to the right edge and the left edge of the bottom wall 56, respectively.

### Support Member

In FIG. 1 and FIG. 4, the pump device P includes a support member 17 which supports the pump 1 at a predetermined height from the bottom wall 56 in the accommodation space 50a of the casing 50. The support member 17 of the present embodiment supports the housing 2 of the pump 1 at a height where the second connection end portion 44b of the second pipe 44 does not come into contact with the bottom wall 56. The support member 17 is formed of a plate member having approximately the same dimension in the left-right direction as the bottom wall 56 and is provided on the upper surface of the bottom wall 56. The support member 17 includes, in order from the rear side toward the front side, a first installation portion 17a, a first leg portion 17b, a placement portion 17c, a second leg portion 17d, and a second installation portion 17e.

The first installation portion 17a and the second installation portion 17e each extend in the front-rear direction. The first installation portion 17a is fixed in a state of being in surface contact with the upper surface of the bottom wall 56, near the first side wall 51. The second installation portion 17e is fixed in a state of being in surface contact with the upper surface of the bottom wall 56, near the second side wall 52.

The first leg portion 17b extends upward and frontward in an inclined manner from the front edge of the first installation portion 17a. The second leg portion 17d extends upward and rearward in an inclined manner from the rear edge of the second installation portion 17e. The first leg portion 17b is longer in the front-rear direction than the second leg portion 17d and is more gently inclined than the second leg portion 17d.

The placement portion 17c extends, parallel to the bottom wall 56, in the front-rear direction. The rear edge of the placement portion 17c is connected to the front edge of the first leg portion 17b. The front edge of the placement portion 17c is connected to the rear edge of the second leg portion 17d. The accommodation space 50a of the casing 50 is formed by being enclosed by the support member 17, the first side wall 51, the second side wall 52, and the top wall 55.

The cylinder 2a of the pump 1 is placed on the upper surface of the placement portion 17c. The cylinder 2a is fixed to the placement portion 17c by a plurality of bolts 18. Accordingly, the support member 17 supports the pump 1 at a predetermined height from the bottom wall 56 in the accommodation space 50a of the casing 50.

In a state where the pump 1 is supported by the support member 17, the pressure sensor 14 connected to the third connection end portion 42c of the first pipe 41 is located at the upper side and the front side (second side wall 52 side) of the accommodation space 50a. A part (rear portion) of the pressure sensor 14 is located above a front end portion of the first leg portion 17b of the support member 17 with the mounting frame 6 interposed therebetween. The motor 11 is located rearward of the pressure sensor 14. The coupling member 12 is placed parallel to and facing the first side wall 51 with the transmission mechanism 13 interposed therebetween.

### Intake Port and Exhaust Port

In FIG. 1, FIG. 5, and FIG. 6, the casing 50 includes an intake port 57, a first exhaust port (exhaust port) 58, and a second exhaust port (exhaust port) 59. The intake port 57 is provided at the lower side of the first side wall 51. The intake port 57 of the present embodiment is a circular hole formed in a lower end portion of the first side wall 51 so as to extend therethrough in the front-rear direction.

The first exhaust port 58 is provided above the intake port 57 in the first side wall 51. The first exhaust port 58 of the present embodiment is composed of a plurality of slits 58a formed above the intake port 57 so as to extend through the first side wall 51 in the front-rear direction at equal intervals in the left-right direction. Each slit 58a extends in the up-down direction at a position, in the first side wall 51, facing the coupling member 12.

The second exhaust port 59 is provided in the top wall 55 located above the intake port 57. The second exhaust port 59 of the present embodiment is composed of a plurality of slits 59a and a plurality of slits 59b formed in the top wall 55. The plurality of slits 59a are formed at the rear side of the top wall 55 so as to extend through the top wall 55 in the up-down direction at equal intervals in the left-right direction. The plurality of slits 59b are formed at the front side of the top wall 55 so as to extend through the top wall 55 in the up-down direction at equal intervals in the left-right direction. Each slit 59a or 59b extends in the front-rear direction in the top wall 55.

Due to the above, gas for cooling the pressure sensor 14, which is a heat-generating component, is introduced into the accommodation space 50a of the casing 50 through the intake port 57. This gas is, for example, air. The gas warmed around the pressure sensor 14 in the accommodation space 50a of the casing 50 is discharged to the outside of the casing 50 through the first exhaust port 58 and the second exhaust port 59.

### Heat Dissipation Portion

In FIG. 1 and FIG. 4, the pump device P includes a heat dissipation portion 70 which dissipates heat generated by the pressure sensor 14 in the accommodation space 50a of the casing 50. The heat dissipation portion 70 of the present embodiment includes a first heat dissipation member 71, a second heat dissipation member 72, and a third heat dissipation member 73 which are placed in the accommodation space 50a.

The first heat dissipation member 71 is provided to the pressure sensor 14. The first heat dissipation member 71 is composed of a pair of left and right split pieces 71a and 71b which are each formed in a substantially semi-cylindrical shape. These split pieces 71a and 71b cover the outer peripheral surface of the pressure sensor 14. Above the pressure sensor 14, end portions of the split pieces 71a and 71b adjacent to each other in the circumferential direction are fixed to each other by a bolt 74. Below the pressure sensor 14, other end portions of the split pieces 71a and 71b adjacent to each other in the circumferential direction are fixed to each other by a bolt 75.

The second heat dissipation member 72 dissipates heat generated by the pressure sensor 14 from the first heat dissipation member 71 to the casing 50. The second heat dissipation member 72 connects an end portion on the front side (first pipe 41 side) of the first heat dissipation member 71 to the top wall 55 of the casing 50. In the present embodiment, the second heat dissipation member 72 is composed of a plate member having approximately the same dimension in the left-right direction as the top wall 55.

The second heat dissipation member 72 is formed in an inverted L-shape in a side view and includes a horizontal plate portion 72a and a vertical plate portion 72b. The horizontal plate portion 72a is fixed to the top wall 55 by a pair of left and right bolts 76 in a state of being in contact with the lower surface of the top wall 55. Each bolt 76 is inserted from above the top wall 55 through the slit 59b and screwed into a threaded hole (not shown) formed in the horizontal plate portion 72a.

The vertical plate portion 72b of the second heat dissipation member 72 extends downward from the rear end of the horizontal plate portion 72a. A lower portion of the vertical plate portion 72b is placed between the third connection end portion 42c of the first pipe 41 and the pressure sensor 14. The pressure sensor 14 is connected to the third connection end portion 42c through the vertical plate portion 72b. The rear surface of the lower portion of the vertical plate portion 72b is in contact with a front end portion of each of the split pieces 71a and 71b of the first heat dissipation member 71. Heat generated by the pressure sensor 14 is dissipated from the front end portion of the first heat dissipation member 71 through the second heat dissipation member 72 to the top wall 55 of the casing 50.

Similar to the second heat dissipation member 72, the third heat dissipation member 73 dissipates heat generated by the pressure sensor 14 from the first heat dissipation member 71 to the casing 50. The third heat dissipation member 73 connects an upper end portion of the first heat dissipation member 71 to the top wall 55 of the casing 50. The third heat dissipation member 73 of the present embodiment is composed of a plate member and is placed perpendicular to the vertical plate portion 72b of the second heat dissipation member 72, at the rear of the second heat dissipation member 72. The front side surface of the third heat dissipation member 73 is in contact with the rear surface of the vertical plate portion 72b.

An upper end portion of the third heat dissipation member 73 is fixed to the top wall 55 by a pair of front and rear bolts 77 in a state of being in surface contact with the lower surface of the top wall 55. Each bolt 77 is inserted from above the top wall 55 through the slit 59b and screwed into a threaded hole (not shown) formed in the third heat dissipation member 73.

A lower end portion of the third heat dissipation member 73 is integrally provided with the split piece 71a of the first heat dissipation member 71. Heat generated by the pressure sensor 14 is dissipated from the upper end portion of the first heat dissipation member 71 through the third heat dissipation member 73 to the top wall 55 of the casing 50. The lower end portion of the third heat dissipation member 73 may be provided separately from the split piece 71a of the first heat dissipation member 71 or may be provided integrally with or separately from the split piece 71b of the first heat dissipation member 71.

### Flow Rectifying Portion

In FIG. 4, the pump device P includes a flow rectifying portion 80 which rectifies the flow of the gas introduced into the accommodation space 50a through the intake port 57 of the casing 50. In FIG. 4, a direction in which the gas flows is indicated by outlined arrows. The flow rectifying portion 80 of the present embodiment includes a first flow rectifying member 81, a second flow rectifying member 82, a third flow rectifying member 83, and a fourth flow rectifying member 84 which are placed in the accommodation space 50a of the casing 50.

The first flow rectifying member 81 is a member that guides the gas introduced into the accommodation space 50a through the intake port 57, from the lower side and the rear side (first side wall 51 side) of the accommodation space 50a to the upper side and the front side (second side wall 52 side) of the accommodation space 50a. In the present embodiment, the first leg portion 17b of the support member 17, which supports the pump 1, also serves as the first flow rectifying member 81.

Therefore, the gas introduced into the accommodation space 50a through the intake port 57 is guided from the lower side and the rear side (first side wall 51 side) of the accommodation space 50a along the first leg portion 17b to the upper side and the front side of the accommodation space 50a. Accordingly, the pressure sensor 14, which is located at the upper side and the front side of the accommodation space 50a, is cooled by the gas. The first flow rectifying member 81 may be a dedicated member separate from the support member 17.

The second flow rectifying member 82 is a member that separates the pressure sensor 14 and the lower pipe portion 42 of the first pipe 41 from each other. The second flow rectifying member 82 inhibits the gas warmed around the pressure sensor 14 from flowing toward the first pipe 41 side. In the present embodiment, the vertical plate portion 72b of the second heat dissipation member 72, which dissipates heat generated by the pressure sensor 14 to the casing 50, also serves as the second flow rectifying member 82.

Therefore, the vertical plate portion 72b can inhibit the gas warmed around the pressure sensor 14 from flowing toward the first pipe 41 side. Since the flow toward the first pipe 41 side is inhibited by the vertical plate portion 72b, a part of the gas warmed around the pressure sensor 14 is discharged to the outside of the casing 50 through the second exhaust port 59 of the top wall 55. The remaining gas warmed around the pressure sensor 14 flows rearward along the top wall 55 at the upper side of the accommodation space 50a. The second flow rectifying member 82 may be a dedicated member separate from the second heat dissipation member 72.

The third flow rectifying member 83 is a member that is placed so as to extend in the up-down direction at the rear side (first side wall 51 side) of the accommodation space 50a and above the intake port 57. In the present embodiment, the coupling member 12, which couples the rear end portions of the pump 1 and the motor 11 with each other, also serves as the third flow rectifying member 83. An exhaust flow path 85 for guiding the gas to the first exhaust port 58 is formed between the coupling member 12 and the first side wall 51. The exhaust flow path 85 is formed so as to extend in the up-down direction between the coupling member 12 and the first side wall 51.

As described above, the gas flowing rearward along the top wall 55 at the upper side of the accommodation space 50a flows into the exhaust flow path 85 and is thereby discharged to the outside of the casing 50 through the first exhaust port 58 of the first side wall 51. The third flow rectifying member 83 may be a dedicated member separate from the coupling member 12.

The fourth flow rectifying member 84 is a member that is placed between a lower end portion of the third flow rectifying member 83 and the first side wall 51. The fourth flow rectifying member 84 of the present embodiment is integrally formed with the lower end portion of the coupling member 12 (third flow rectifying member 83). The fourth flow rectifying member 84 protrudes rearward from the lower end portion of the coupling member 12. The protruding end face on the rear side of the fourth flow rectifying member 84 is in contact with the front surface of the first side wall 51. Accordingly, the fourth flow rectifying member 84 closes the lower end of the exhaust flow path 85. The fourth flow rectifying member 84 may be integrally formed with the first side wall 51 or may be provided as a separate component from both the first side wall 51 and the third flow rectifying member 83.

### Advantageous Effects

With the pump device P of the first embodiment, the pressure sensor 14, which is a heat-generating component placed in the accommodation space 50a of the casing 50, is cooled by the gas introduced through the intake port 57 of the casing 50. The gas warmed around the pressure sensor 14 is discharged to the outside of the casing 50 through the first exhaust port 58 and the second exhaust port 59. Accordingly, the temperature of the pressure sensor 14 becomes less likely to increase, and thus an increase in the temperature of the transport fluid caused by an increase in the temperature of the pressure sensor 14 can be suppressed. As a result, deterioration of the transport fluid due to thermal effects can be suppressed.

The heat dissipation portion 70, which dissipates heat generated by the pressure sensor 14, is placed in the accommodation space 50a of the casing 50. Therefore, owing to the heat dissipation portion 70, the temperature of the pressure sensor 14 becomes further less likely to increase, and thus an increase in the temperature of the transport fluid caused by an increase in the temperature of the pressure sensor 14 can be further suppressed.

The flow of the gas introduced into the accommodation space 50a through the intake port 57 of the casing 50 is rectified by the flow rectifying portion 80. Accordingly, the pressure sensor 14 can be efficiently cooled.

The first flow rectifying member 81 guides the gas introduced into the accommodation space 50a through the intake port 57 of the casing 50, from the lower side and the rear side of the accommodation space 50a to the upper side and the front side of the accommodation space 50a. Therefore, the first flow rectifying member 81 can efficiently cause the gas introduced into the accommodation space 50a through the intake port 57, to flow toward the pressure sensor 14. Accordingly, the pressure sensor 14 can be further efficiently cooled.

The support member 17, which supports the pump 1 at a predetermined height from the bottom wall 56 of the casing 50, also serves as the first flow rectifying member 81 which guides the flow of the gas. Accordingly, the configuration of the pump device P can be simplified.

The second flow rectifying member 82 separates the pressure sensor 14 and the first pipe 41 from each other. Therefore, the second flow rectifying member 82 can inhibit the gas warmed around the pressure sensor 14 from flowing toward the first pipe 41 side. Accordingly, an increase in the temperature of the transport fluid flowing through the first pipe 41 can be suppressed.

The second heat dissipation member 72, which dissipates heat generated by the pressure sensor 14 from the first heat dissipation member 71 to the top wall 55 of the casing 50, also serves as the second flow rectifying member 82 which separates the pressure sensor 14 and the first pipe 41 from each other. Accordingly, the configuration of the pump device P can be further simplified.

The third flow rectifying member 83 is placed so as to extend in the up-down direction at the rear side of the accommodation space 50a of the casing 50 and above the intake port 57. The exhaust flow path 85 for guiding the gas to the first exhaust port 58 is formed between the third flow rectifying member 83 and the first side wall 51. Therefore, owing to the exhaust flow path 85, the gas warmed around the pressure sensor 14 can be efficiently discharged to the outside of the casing 50 through the first exhaust port 58 of the first side wall 51.

The coupling member 12, which couples the rear end portions of the pump 1 and the motor 11 with each other, also serves as the third flow rectifying member 83 which forms the exhaust flow path 85. Accordingly, the configuration of the pump device P can be further simplified.

The fourth flow rectifying member 84 is placed between the lower end portion of the coupling member 12 (third flow rectifying member 83) and the first side wall 51 and closes the lower end of the exhaust flow path 85. Therefore, the fourth flow rectifying member 84 can prevent the gas flowing from the upper side toward the lower side of the exhaust flow path 85 from merging with the gas introduced through the intake port 57. Accordingly, the gas warmed around the pressure sensor 14 can be inhibited from circulating in the accommodation space 50a of the casing 50.

### Second Embodiment

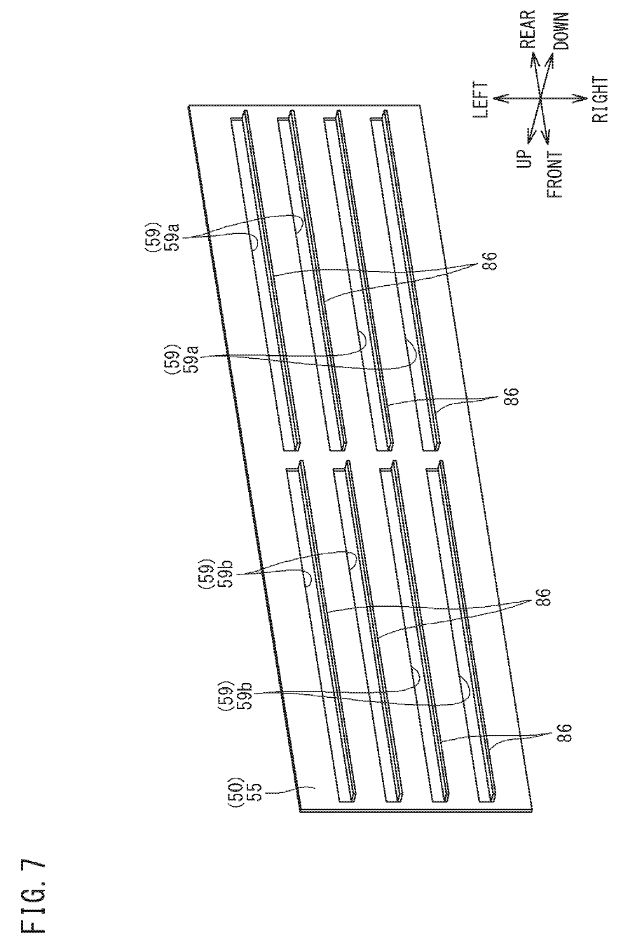

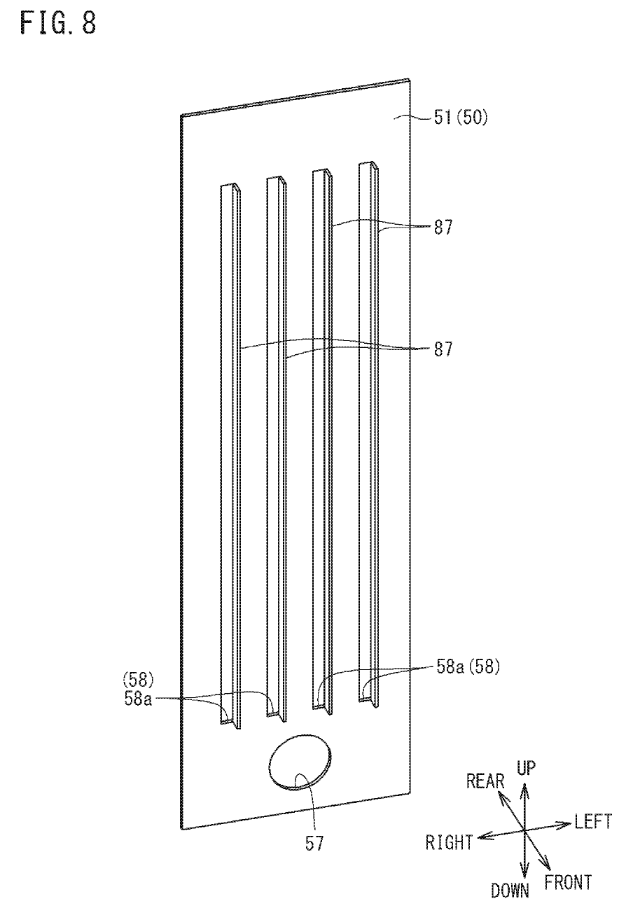

FIG. 7 is a perspective view of a top wall 55 of a casing 50 in a pump device P according to a second embodiment of the present disclosure as seen from an accommodation space 50a side. FIG. 8 is a perspective view of a first side wall 51 of the casing 50 of the second embodiment as seen from the accommodation space 50a side. The present embodiment is different from the first embodiment in that the flow rectifying portion 80 further includes a plurality of first fin members 86 and a plurality of second fin members 87.

In FIG. 7, the plurality of first fin members 86 are provide to the top wall 55. Specifically, the plurality of first fin members 86 are provided at edge portions, extending in the front-rear direction (one direction), of the plurality of slits 59a and 59b which are the second exhaust port 59. Each first fin member 86 of the present embodiment is provided at a right edge portion of the slit 59a or 59b. Each first fin member 86 is provided so as to protrude downward from the edge portion of the slit 59a or 59b toward the accommodation space 50a (see FIG. 4).

Each first fin member 86 extends in the front-rear direction along the edge portion of the slit 59a or 59b. Each first fin member 86 of the present embodiment extends over the entirety of the edge portion of the slit 59a or 59b in the front-rear direction. Each first fin member 86 guides the gas near the top wall 55 at the upper side of the accommodation space 50a (see FIG. 4) such that the gas flows from the front side toward the rear side.

At least one of the plurality of first fin members 86 may be provided at a left edge portion of the slit 59a or 59b. In addition, each first fin member 86 may be provided at a part of the edge portion of the slit 59a or 59b in the front-rear direction.

In FIG. 8, the plurality of second fin members 87 are provided to the first side wall 51. Specifically, the plurality of second fin members 87 are provided at edge portions, extending in the up-down direction (one direction), of the plurality of slits 58a which are the first exhaust port 58. Each second fin member 87 of the present embodiment is provided at a left edge portion of the slit 58a. Each second fin member 87 is provided so as to protrude frontward from the edge portion of the slit 58a toward the accommodation space 50a (see FIG. 4).

Each second fin member 87 extends in the up-down direction along the edge portion of the slit 58a. Each second fin member 87 of the present embodiment extends over the entirety of the edge portion of the slit 58a in the up-down direction. Each second fin member 87 guides the gas near the first side wall 51 in the exhaust flow path 85 (see FIG. 4) such that the gas flows from the upper side toward the lower side.

At least one of the plurality of second fin members 87 may be provided at a right edge portion of the slit 58a. In addition, each second fin member 87 may be provided at a part of the edge portion of the slit 58a in the up-down direction.

The other components of the present embodiment are the same as those of the first embodiment, and thus are designated by the same reference signs, and the description thereof is omitted. The pump device P of the second embodiment also achieves the same advantageous effects as in the first embodiment. In addition, the gas is rectified by the plurality of first fin members 86 which extend along the front-rear direction at the edge portions of the plurality of slits 59a and 59b which are the second exhaust port 59 of the top wall 55. Accordingly, the gas can be inhibited from staying near the top wall 55 of the accommodation space 50a.

Moreover, the gas is rectified by the plurality of second fin members 87 which extend along the up-down direction at the edge portions of the plurality of slits 58a which are the first exhaust port 58 of the first side wall 51. Accordingly, the gas can be inhibited from staying near the first side wall 51 of the accommodation space 50a.

The flow rectifying portion 80 only needs to include at least either the first fin members 86 or the second fin members 87.

### Others

In the pump device P of the present embodiment, the pump 1 accommodated in the casing 50 is a diaphragm pump but may be a pump other than a diaphragm pump. The heat-generating component is not limited to the pressure sensor 14. For example, since the motor 11 includes a stator that generates heat when energized, if the motor 11 is placed at a position where the transport fluid is affected by heat, the motor 11 may be considered as a heat-generating component.

The embodiments disclosed herein are merely illustrative and not restrictive in all aspects. The scope of the present invention is defined by the scope of the claims rather than the meaning described above, and is intended to include meaning equivalent to the scope of the claims and all modifications within the scope.

### REFERENCE SIGNS LIST

1 pump

11 motor

12 coupling member

14 pressure sensor (heat-generating component)

17 support member

40 pipe

50 casing

50a accommodation space

51 first side wall

52 second side wall

56 bottom wall

57 intake port

58 first exhaust port (exhaust port)

58a slit

59 second exhaust port (exhaust port)

59a, 59b slit

70 heat dissipation portion

71 first heat dissipation member

72 second heat dissipation member

80 flow rectifying portion

81 first flow rectifying member

82 second flow rectifying member

83 third flow rectifying member

84 fourth flow rectifying member

85 exhaust flow path

86 first fin member (fin member)

87 second fin member (fin member)

P pump device

1. A pump device comprising: a pump configured to suck and discharge a transport fluid; a casing having an accommodation space in which the pump is accommodated; and a heat-generating component placed in the accommodation space together with the pump, wherein
the casing includes
an intake port for introducing gas for cooling the heat-generating component, into the accommodation space therethrough, and
an exhaust port, located above the intake port, for discharging the gas around the heat-generating component to the outside of the casing therethrough.

2. The pump device according to claim 1, further comprising a heat dissipation portion placed in the accommodation space and configured to dissipate heat generated by the heat-generating component.

3. The pump device according to claim 1, further comprising a flow rectifying portion configured to rectify flow of the gas introduced into the accommodation space through the intake port.

4. The pump device according to claim 3, wherein
the casing includes a first side wall and a second side wall facing each other across the accommodation space,
the intake port is provided at a lower side of the first side wall,
the heat-generating component is a pressure sensor located at an upper side and the second side wall side of the accommodation space and configured to detect a pressure of the transport fluid, and
the flow rectifying portion includes a first flow rectifying member configured to guide the gas introduced into the accommodation space through the intake port, from a lower side and the first side wall side of the accommodation space to the upper side and the second side wall side of the accommodation space.

5. The pump device according to claim 4, wherein
the casing includes a bottom wall placed below the accommodation space,
the pump device further comprises a support member provided to the bottom wall and configured to support the pump at a predetermined height from the bottom wall in the accommodation space, and
the support member also serves as the first flow rectifying member.

6. The pump device according to claim 4, further comprising a pipe which is placed between the pressure sensor and the second side wall in the accommodation space and through which the transport fluid flows, wherein
the flow rectifying portion includes a second flow rectifying member separating the pressure sensor and the pipe from each other.

7. The pump device according to claim 6, further comprising a heat dissipation portion placed in the accommodation space and configured to dissipate heat generated by the heat-generating component, wherein
the heat dissipation portion includes
a first heat dissipation member covering the pressure sensor, and
a second heat dissipation member configured to dissipate heat generated by the pressure sensor, from an end portion on the pipe side of the first heat dissipation member to the casing, and
the second heat dissipation member also serves as the second flow rectifying member.

8. The pump device according to claim 4, wherein
the exhaust port is provided above the intake port in the first side wall,
the flow rectifying portion includes a third flow rectifying member placed so as to extend in an up-down direction at the first side wall side of the accommodation space and above the intake port, and
an exhaust flow path for guiding the gas to the exhaust port is formed between the third flow rectifying member and the first side wall.

9. The pump device according to claim 8, further comprising:
a motor placed above the pump in the accommodation space; and
a coupling member placed in the accommodation space, extending in the up-down direction, and coupling end portions on the first side wall side of the pump and the motor with each other, wherein
the coupling member also serves as the third flow rectifying member.

10. The pump device according to claim 8, wherein the flow rectifying portion includes a fourth flow rectifying member placed between a lower end portion of the third flow rectifying member and the first side wall and closing a lower end of the exhaust flow path.

11. The pump device according to claim 3, wherein
the exhaust port is composed of a plurality of slits formed in the casing and extending in one direction, and
the flow rectifying portion includes a plurality of fin members provided so as to protrude from edge portions, extending in the one direction, of the slits toward the accommodation space and extending along the one direction.
